(19) United States
(12) Patent Application Publication
(10) Pub. No.: US 2015/0041941 A1
(43) Pub. Date: Feb. 12, 2015

(54) SOLID-STATE IMAGING DEVICE

(71) Applicant: Kabushiki Kaisha Toshiba, Minato-ku (JP)

(72) Inventor: Soichiro UENO, Tokyo (JP)

(73) Assignee: Kabushiki Kaisha Toshiba, Minato-ku (JP)

(21) Appl. No.: 14/200,450

(22) Filed: Mar. 7, 2014

(30) Foreign Application Priority Data
Aug. 12, 2013 (JP) 2013-167581

(51) Int. Cl. H01L 27/146

(52) U.S. Cl. CPC H01L 27/14621; H01L 27/14625
USPC 257/432

(57) ABSTRACT

According to one embodiment, a solid-state imaging device including a semiconductor substrate having a light receiving portion, a color filter layer and a selective reflection layer. The color filter layer includes a color filter portion and is provided above a first main surface of the semiconductor substrate. The color filter portion has a transmission band for transmitting light of a predetermined wavelength band and absorbs light outside the transmission band. The selective reflection layer is provided between the first main surface of the semiconductor substrate and the color filter layer so as to contact with the color filter portion. The selective reflection layer has substantially the same refraction index as the color filter portion with respect to light within the transmission band. The refraction index of the selective reflection layer is substantially different from that of the color filter portion with respect to light outside the transmission band.

### CROSS-REFERENCE TO RELATED APPLICATION

This application is based upon and claims the benefit of priority from the prior Japanese Patent Application No. 2013-167581, filed on Aug. 12, 2013, the entire contents of which are incorporated herein by reference.

### FIELD

Embodiments described herein relate generally to a solid-state imaging device.

### BACKGROUND

A solid-state imaging device for use in a CMOS image sensor etc. is configured such that a plurality of pixels is arrayed planarly. Each pixel has a light receiving portion for receiving light and a microlens which collects light onto the light receiving portion.

In a solid-state imaging device which photographs a color image, a color filter layer having color filter portions is provided. The color filter portions are arranged between light receiving portions and microlenses. The light transmission bands of the color filter portions are different from each other. Each of the color filter portions transmits light within the transmission band and absorbs light outside the transmission band so that each pixel can receive light having a different color. For example, the color filter portions are a blue color filter portion which transmits blue light, a green color filter portion which transmits green light, and a red color filter portion which transmits red light.

The color filter portions are generally formed in such a manner that a suitable pigment or dye is selected and the selected pigment or dye is mixed into a transparent resin so as to be contained in the transparent resin capable of patterning, in order to adjust light transmission band or absorption rate of light outside the light transmission band.

However, since a spectral characteristic of each pixel of the solid-state imaging device having the color filter portions formed in this manner is restricted depending on a kind of pigment or dye contained in the transparent resin, it is difficult to improve the spectral characteristic further. The spectral characteristic is a characteristic to separate light within a predetermined wavelength band from light outside the wavelength band such that only the light within the predetermined wavelength band reaches the light receiving portion of each pixel.

### BRIEF DESCRIPTION OF THE DRAWINGS

FIG. 1 is a top view schematically illustrating a solid-state imaging device according to a first embodiment.

FIG. 2 is a cross-sectional view taken along the dashed-dotted line X-X indicated in the solid-state imaging device.

FIG. 3 is a cross-sectional view taken along the dashed-dotted line Y-Y indicated in the solid-state imaging device.

FIGS. 4A to 4C are explanatory diagrams for explaining a relation between a blue color filter portion and a selective reflection portion, FIG. 4A is a diagram illustrating the wavelength dependence of light absorption rate in the blue color filter portion, FIG. 4B is a diagram illustrating the wavelength dependence of refraction index of the selective reflection portion, and FIG. 4C is a diagram illustrating the wavelength dependence of light reflection rate at an interface between the blue color filter portion and the selective reflection portion.

FIG. 5 is a diagram illustrating the wavelength dependence of intensity of light which reaches a light receiving portion within a blue pixel having a blue color filter portion and a selective reflection portion.

FIG. 6 is a cross-sectional view of a solid-state imaging device according to a first modification of the first embodiment, which corresponds to FIG. 2.

FIG. 7 is a cross-sectional view of the solid-state imaging device according to the first modification of FIG. 6, which corresponds to FIG. 3.

FIGS. 8A to 8C are explanatory diagrams for explaining a relation between a green color filter portion and a selective reflection portion, FIG. 8A is a diagram illustrating the wavelength dependence of light absorption rate in the green color filter portion, FIG. 8B is a diagram illustrating the wavelength dependence of refraction index of the selective reflection portion, and FIG. 8C is a diagram illustrating the wavelength dependence of light reflection rate at an interface between the green color filter portion and the selective reflection portion.

FIG. 9 is a diagram illustrating the wavelength dependence of intensity of light which reaches a light receiving portion within a green pixel having a green color filter portion and a selective reflection portion.

FIG. 10 is a cross-sectional view of a solid-state imaging device according to a second modification of the first embodiment, which corresponds to FIG. 2.

FIG. 11 is a cross-sectional view of the solid-state imaging device according to the second modification of FIG. 10, which corresponds to FIG. 3.

FIGS. 12A to 12C are explanatory diagrams for explaining a relation between a red color filter portion and a selective reflection portion, FIG. 12A is a diagram illustrating the wavelength dependence of light absorption rate in the red color filter portion, FIG. 12B is a diagram illustrating the wavelength dependence of refraction index of the selective reflection portion, and FIG. 12C is a diagram illustrating the wavelength dependence of light reflection rate at an interface between the red color filter portion and the selective reflection portion.

FIG. 13 is a diagram illustrating the wavelength dependence of intensity of light which reaches a light receiving portion within a red pixel having a red color filter portion and a selective reflection portion.

FIG. 14 is a cross-sectional view of a solid-state imaging device according to a second embodiment, which corresponds to FIG. 2.

FIG. 15 is a cross-sectional view of the solid-state imaging device of FIG. 14, which corresponds to FIG. 3.

FIG. 16 is a cross-sectional view of a solid-state imaging device according to a third modification of the first embodiment, which corresponds to FIG. 2.

### DETAILED DESCRIPTION

According to one embodiment, a solid-state imaging device including a semiconductor substrate having a light receiving portion, a color filter layer and a selective reflection layer. The color filter layer includes a color filter portion and is provided above a first main surface of the semiconductor substrate. The color filter portion has a transmission band for transmitting light of a predetermined wavelength band and absorbs light outside the transmission band. The selective reflection layer is provided between the first main surface of the semiconductor substrate and the color filter layer so as to contact with the color filter portion. The selective reflection layer has substantially the same refraction index as the color filter portion with respect to light within the transmission band. The refraction index of the selective reflection layer is substantially different from that of the color filter portion with respect to light outside the transmission band.

Hereinafter, further embodiments will be described with reference to the drawings. In the drawings, the same reference numerals denote the same or similar portions respectively.

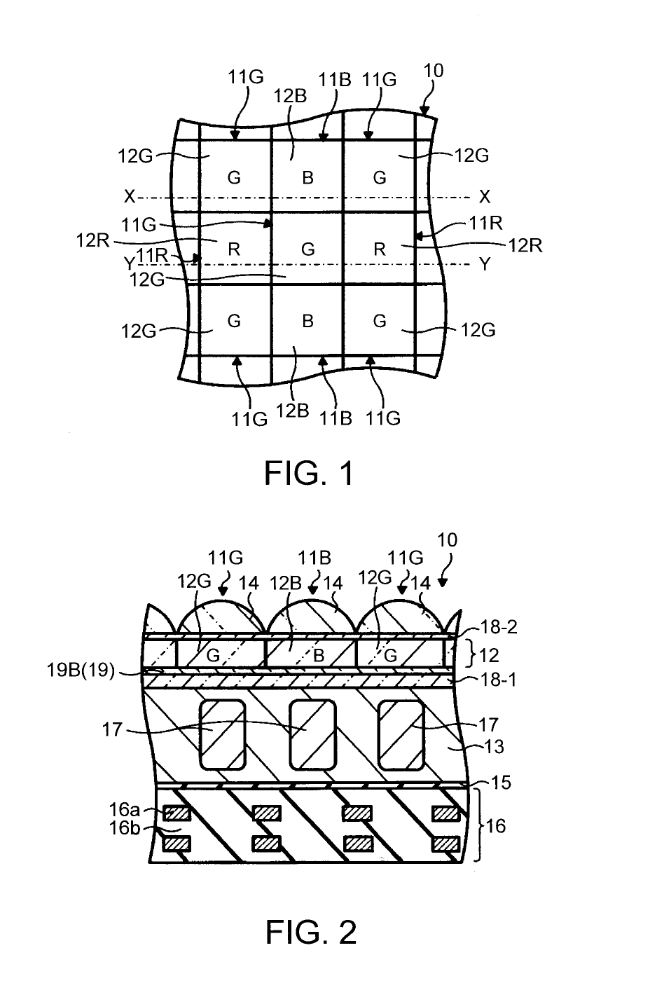

A first embodiment will be described with reference to FIG. 1. FIG. 1 is a top view schematically illustrating a solid-state imaging device according to the first embodiment.

As illustrated in FIG. 1, a solid-state imaging device 10 according to the first embodiment is configured such that pixels 11B, 11G, 11R are arrayed in a lattice form.

The pixels 11B have a blue color filter portion 12B. The pixels 11G have a green color filter portion 12G. The pixels 11R have a red color filter portion 13R.

The pixels 11B, 11G, 11R are provided such that the blue color filter portion 12B, the green color filter portion 12G, and the red color filter portion 12R are Bayer-arrayed. In FIG. 1, a microlens which will be described below is not shown.

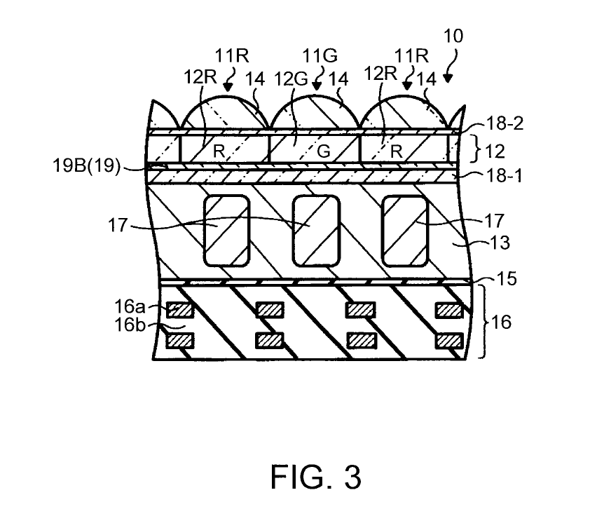

FIG. 2 is a cross-sectional view taken along the dashed-dotted line X-X indicated in the solid-state imaging device 10 of FIG. 1. FIG. 3 is a cross-sectional view taken along the dashed-dotted line Y-Y indicated in the solid-state imaging device 10 of FIG. 1.

As illustrated in FIGS. 2 and 3, the solid-state imaging device 10 according to the embodiment has a color filter layer 12 and microlenses 14 above a back surface which is a first main surface of a semiconductor substrate 13. A layer 16 having interconnections 16a is formed above a front surface which is a second main surface of the semiconductor substrate 13, via an insulating film 15. The solid-state imaging device 10 is a so-called back-surface irradiation type.

The layer 16 is configured in such a manner that interconnections 16a are insulated from each other by an interlayer insulating film 16b. The interconnections 16a are connected to gate transistors (not illustrated) in order to read charges generated in light receiving portions 17 described below.

In the solid-state imaging device 10, the light receiving portions 17 are provided in the semiconductor substrate 13. Each of the light receiving portions 17 is, for example, a photodiode layer which is formed by implanting impurities onto the semiconductor substrate 13. Each of the light receiving portions 17 is provided in each of the pixels 11B, 11G, 11R illustrated in FIG. 1. Accordingly, the light receiving portions 17 are formed so as to be arrayed in a lattice form depending on the structure of the array of the pixels 11B, 11G, 11R.

A first flattened layer 18-1 is provided above the back surface of the semiconductor substrate 13 having the light receiving portions 17. The first flattened layer 18-1 is made of, for example, a transparent resin layer capable of transmitting at least visible light. Moreover, the first flattened layer 18-1 is provided such that the surface is flattened to reduce an unevenness of the back surface of the semiconductor substrate 13.

A selective reflection layer 19 and a color filter layer 12 are laminated above the surface of the first flattened layer 18-1 in this order. The selective reflection layer 19 is a layer which reflects light selectively depending on a wavelength of incident light.

The color filter layer 12 includes the blue color filter portions 12B, the green color filter portions 12G, and the red color filter portions 12R. The blue color filter portion 12B has a blue wavelength band (about 450 to 495 nm) as a transmission band for absorbing light outside the transmission band. The green color filter portion 12G has a green wavelength band (about 495 to 570 nm) as a transmission band for absorbing light outside the transmission band. The red color filter portion 12R has a red wavelength band (about 620 to 750 nm) as a transmission band for absorbing light outside the transmission band.

For example, each of the color filter portions 12B, 12G, 12R is formed in such a manner that a predetermined organic substance such as a pigment or dye is mixed into a transparent resin capable of patterning so as to adjust the transmission band and the absorption rate of the light outside the transmission band.

As described above, each of the color filter portions 12B, 12G, 12R is included in each of the pixels 11B, 11G, 11R. Accordingly, in the color filter layer 12, the above-described color filter portions 12B, 12G, 12R are arrayed in a lattice form and are also Bayer-arrayed.

The selective reflection layer 19 is provided between the back surface of the semiconductor substrate 13 and the color filter layer 12 so as to contact with the color filter layer 12. The selective reflection layer 19 is one-layered selective reflection portion 19B which is provided to contact with at least the blue color filter portion 12B, for example. The selective reflection portion 19B transmits blue light transmitted through the blue color filter portion 12B and reflects light other than blue light at an interface with the blue color filter portion 12B. The selective reflection portion 19B is a portion which reflects light selectively depending on the wavelength of incident light.

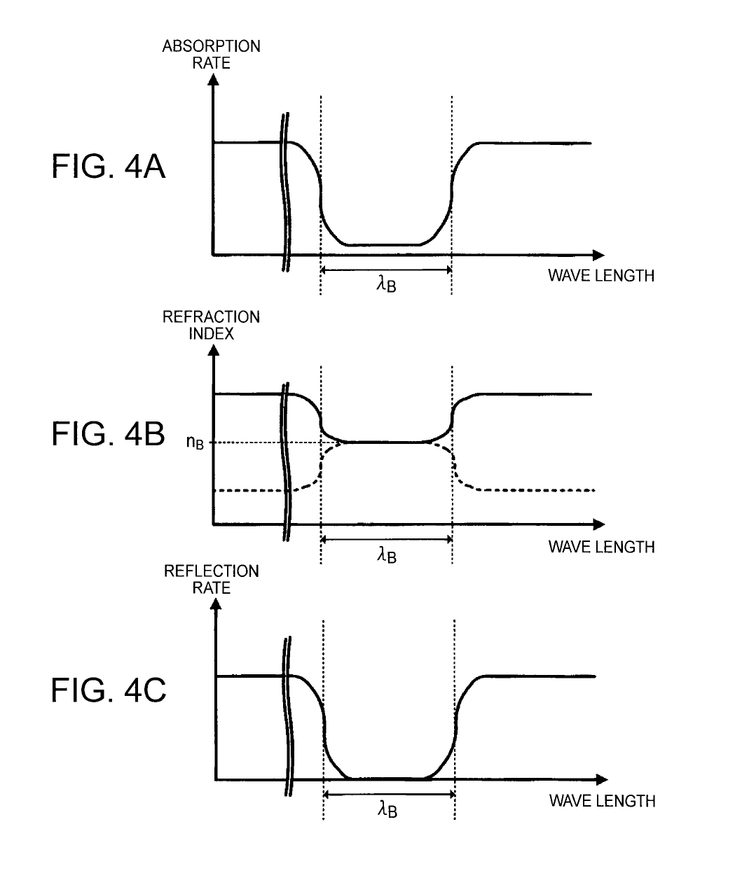

The relation between the blue color filter portion 12B and the selective reflection portion 19B will be described below with reference to FIGS. 4A to 4C. FIG. 4A is a diagram illustrating the wavelength dependence of light absorption rate in the blue color filter portion 12B. FIG. 4B is a diagram illustrating the wavelength dependence of refraction index of the selective reflection portion 19B. FIG. 4C is a diagram illustrating the wavelength dependence of light reflection rate at an interface between the blue color filter portion 12B and the selective reflection portion 19B.

As illustrated in FIG. 4A, the blue color filter portion 12B is formed by selecting a substance to be contained so that the light absorption rate is low within a blue wavelength band λ_{B} (λ_{B} is about 450 to 495 nm) and the light absorption rate is high outside the blue wavelength band λ_{B}. For example, a blue pigment is made to be contained in a transparent resin so that the blue color filter portion 12B is formed. The blue color filter portion 12B transmits blue light and absorbs light other than blue light mostly.

As illustrated in FIG. 4B, the refraction index of the selective reflection portion 19B within the blue wavelength band λ_{B} coincides with a refraction index n_{B} of the blue color filter portion 12B substantially. The refraction index of the selective reflection portion 19B outside the blue wavelength band λ_{B} is provided so as to differ from the refraction index n_{B} of the blue color filter portion 12B substantially, for example, so as to be higher than the refraction index n_{B} of the blue color filter portion 12B. The selective reflection portion 19B may be formed in such a manner that a predetermined organic substance such as a metal or an inorganic substance is mixed into a transparent resin which is capable of patterning to adjust the refraction index.

For example, the refraction index n_{B} of the blue color filter portion 12B containing the blue pigment is about 1.4 to 1.6. When such a blue color filter portion 12B is used, filler is made to be contained in the transparent resin so that the selective reflection portion 19B can be formed, for example. The refraction index of the selective reflection portion 19B formed in this manner within the blue wavelength band λ_{B} is close to the refraction index of the blue color filter portion 12B or coincides with the refraction index of the blue color filter portion 12B substantially. Further, the refraction index of the selective reflection portion 19B outside the blue wavelength band λ_{B} is quite different from the refraction index of the blue color filter portion 12B and becomes higher than the refraction index of the blue color filter portion 12B.

With respect to light incident on an interface between an object A having a refraction index na and an object B having a refraction index nb, the reflection rate at the interface between the object A and the object B is determined according to Huygens' principle and Snell's law. When the refraction index na of the object A and the refraction index nb of the object B are equal to each other, the reflection is minimized. When the refraction index na of the object A and the refraction index nb of the object B are different from each other, the reflection occurs at the interface between both of the objects. The reflection becomes larger, as the difference between the refraction index na of the object A and the refraction index nb of the object B is greater.

According to the above relation, as described above, the selective reflection portion 19B is provided so that the refraction index of the blue color filter portion 12B coincides with the refraction index of the selective reflection portion 19B substantially within the blue wavelength band λ_{B}. Accordingly, as illustrated in FIG. 4C, a blue light transmitted through the blue color filter portion 12B is not reflected at the interface between the blue color filter portion 12B and the selective reflection portion 19B but penetrates into the selective reflection portion 19B.

The refraction index of the blue color filter portion 12B differs from the refraction index of the selective reflection portion 19B substantially outside the blue wavelength band λ_{B}. Accordingly, as illustrated in FIG. 4C, a light other than blue light transmitted through the blue color filter portion 12B is not absorbed in the blue color filter portion 12B but is reflected at the interface between the blue color filter portion 12B and the selective reflection portion 19B.

The selective reflection portion 19B is provided so as to have the refraction index characteristic as illustrated in FIG. 4B, so that the selective reflection portion 19B can transmit a blue light transmitted through the blue color filter portion 12B and reflect a light other than blue light at the interface with the blue color filter portion 12B.

It is possible to increase the reflection quantity of a light other than blue light reflected at the interface more, as the difference between the refraction index of the blue color filter portion 12B and the refraction index of the selective reflection portion 19B become greater outside the blue wavelength band λ_{B}.

As described above, the selective reflection portion 19B reflects a light other than a blue light at the interface by the difference with the refraction index of the blue color filter portion 12B. In order to achieve the effect, the selective reflection portion 19B needs to have at least one wavelength. For example, the selective reflection portion 19B in the blue pixel 11B needs to have a thickness of about one wavelength of the blue light.

As described above, it is sufficient that the selective reflection portion 19B is provided such that the refraction index of the selective reflection portion 19B differs from the refraction index of the blue color filter portion 12B with respect to a light outside the blue wavelength band λ_{B}. Accordingly, as illustrated by the dotted line in FIG. 4B, the selective reflection portion 19B may be provided such that the refraction index of the selective reflection portion 19B is lower than the refraction index n_{B} of the blue color filter portion 12B with respect to the light outside the blue wavelength band λ_{B}.

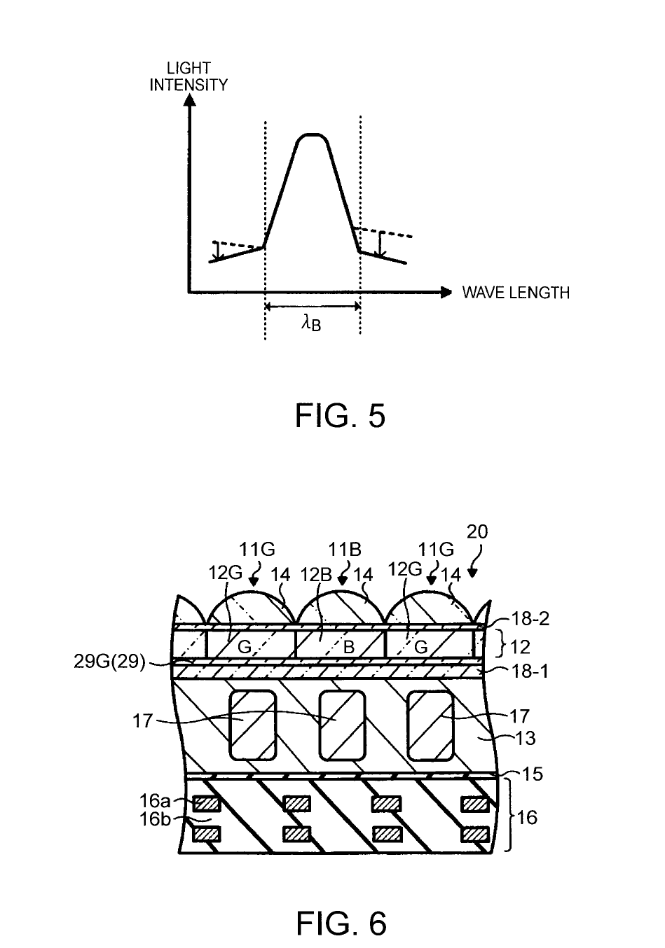

FIG. 5 is a diagram illustrating the wavelength dependence of intensity of light which reaches a light receiving portion 17 of the blue pixel 11B having the blue color filter portion 12B and the selective reflection portion 19B illustrated in FIGS. 1 to 3. As described above, the selective reflection portion 19B is provided so that a blue light transmitted through the blue color filter portion 12B is transmitted through the selective reflection portion 19B to reach the light receiving portion 17. Accordingly, as illustrated in FIG. 5, the blue light reaches the light receiving portion 17 at a large light intensity in the blue pixel 11B.

A light other than blue light which is not absorbed in the blue color filter portion 12B but is transmitted through the color filter portion 12B is reflected at the interface between the blue color filter portion 12B and the selective reflection portion 19B. Accordingly, as illustrated in FIG. 5, the intensity of the light other than blue light which reaches the light receiving portion 17 is small in the blue pixel 11B.

On the other hand, in a case of a solid-state imaging device not having such a selective reflection portion, almost all of the light other than blue light, which is transmitted through the blue color filter portion in the blue pixel, reaches the light receiving portion. Accordingly, as illustrated by the dotted line in FIG. 5, the intensity of the light other than blue light which reaches the light receiving portion in the blue pixel of the solid-state imaging device becomes high compared to the blue pixel 11B in the solid-state imaging device 10 according to the embodiment. This is one of factors which reduce a spectral characteristic in the blue pixel.

Referring again to FIGS. 2 and 3, a second flattened layer 18-2 is provided above the front surface of the selective reflection layer 19. The second flattened layer 18-2 is made of a transparent resin layer capable of transmitting at least visible light, for example, and is provided such that the surface is flattened to reduce an unevenness of the surface of the selective reflection layer 19.

The microlenses 14 are provided above the surface of the second flattened layer 18-2 for each of the pixels 11B, 11G, 11R. Each microlens 14 collects light which is incident on the microlens onto the light receiving portions 17 of the pixels 11B, 11G, 11R corresponding to the microlenses.

The solid-state imaging device 10 is manufactured as follows, for example. Ions are selectively implanted into the semiconductor substrate 13 so that the light receiving portions 17 are formed. After the implantation, the layer 16 having the interconnections 16a is formed above the front surface of the semiconductor substrate 13 via the insulating film 15. Further, the first flattened layer 18-1 and the selective reflection layer 19 are formed above the back surface of the semiconductor substrate 11 in this order. Subsequently, the color filter layer 12 having the blue color filter portion 12B, the green color filter portion 12G and the red color filter portion 12R is formed by different processes. Each of the processes includes a forming process and a patterning process of a filter film, for example. After the formation of the color filter layer 12, the second flattened layer 18-2 is formed, and finally the microlenses 14 are formed so that the solid-state imaging device 10 is completed.

According to the solid-state imaging device 10 described above, the selective reflection portion 19B is provided between the back surface of the semiconductor substrate 13 and the blue color filter portion 12B so as to contact with the blue color filter portion 12B. The selective reflection portion 19B has the refraction index which coincides with the refraction index n_{B} of the blue color filter portion 12B substantially with respect to the light within the wavelength band λ_{B} i.e. within the transmission band of the blue light transmitted through the blue color filter portion 12B. Further, the selective reflection portion 19B has the refraction index which differs from the refraction index of the blue color filter portion 12B substantially with respect to a light outside the transmission band λ_{B}. Accordingly, the spectral characteristics can be favorable in at least the blue pixel 11B.

In the solid-state imaging device 10, the selective reflection layer 19 includes the one-layered selective reflection portion 19B. The selective reflection portion 19B transmits a blue light transmitted through the blue color filter portion 12B and reflects a light other than blue light at the interface with the blue color filter portion 12B. Instead of the one-layered selective reflection portion 19B, another kind of one-layered selective reflection portion may be used so as to transmit a green light transmitted through the green color filter portion 12G and to reflect a light other than green light at the interface with the green color filter portion 12G. In addition, instead of the one-layered selective reflection portion 19B, further another kind of one-layered selective reflection portion may be used so as to transmit a red light transmitted through the red color filter portion 12R and to reflect a light other than red light at the interface with the red color filter portion 12R. The former is a first modification and the latter is a second modification. Hereinafter, the first and second modifications will be described.

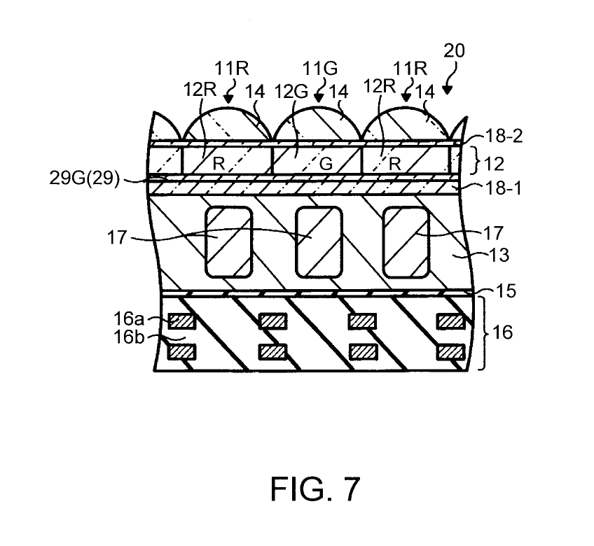

FIGS. 6 and 7 are cross-sectional views illustrating a solid-state imaging device according to the first modification of the first embodiment. FIG. 6 is a cross-sectional view of the solid-state imaging device according to the first modification, which corresponds to FIG. 2. FIG. 7 is a cross-sectional view of the solid-state imaging device according to the first modification, which corresponds to FIG. 3. The top view of the solid-state imaging device according to the first modification is the same as FIG. 1.

As illustrated in FIGS. 6 and 7, in a solid-state imaging device 20 according to the first modification, a selective reflection layer 29 includes one-layered selective reflection portion 29G which transmits green light transmitted through a green color filter portion 12G and reflects light other than green light at an interface with the green color filter portion 12G, as described above.

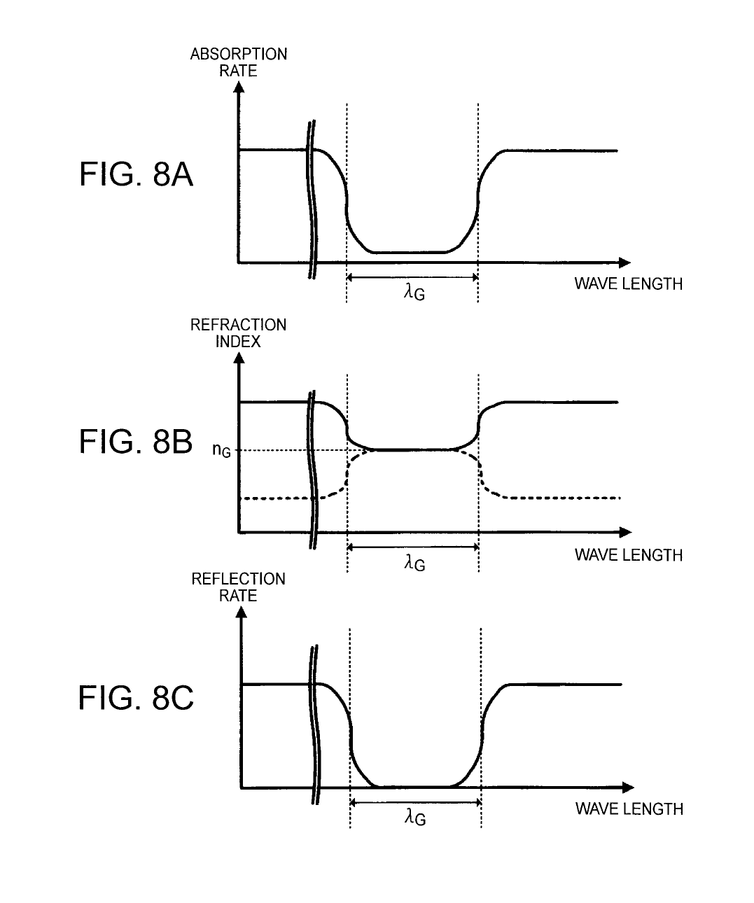

The relation between the green color filter portion 12G and the selective reflection portion 29G will be described below with reference to FIGS. 8A to 8C. FIGS. 8A to 8C are explanatory diagrams for explaining the relation between the green color filter portion 12G and the selective reflection portion 29G. FIG. 8A is a diagram illustrating the wavelength dependence of light absorption rate in the green color filter portion 12G. FIG. 8B is a diagram illustrating the wavelength dependence of refraction index of the selective reflection portion 29G. FIG. 8C is a diagram illustrating the wavelength dependence of reflection rate at an interface between the green color filter portion 12G and the selective reflection portion 29G.

As illustrated in FIG. 8A, the green color filter portion 12G is formed by adjusting a substance to be contained such that the light absorption rate within a green wavelength band λ_{G} (λ_{G} is about 495 to 570 nm) is low and the light absorption rate outside the green wavelength band λ_{G} is high. For example, a green pigment is mixed into a transparent resin so as to be contained in the transparent resin so that the green color filter portion is formed. The green color filter portion 12G transmits green light and mostly absorbs light other than green light.

As illustrated in FIG. 8B, the selective reflection portion 29G is provided such that the refraction index of light within the green wavelength band λ_{G} coincides with a refraction index n_{G} of the green color filter portion 12G substantially. Further, the selective reflection portion 29G is provided such that the refraction index of light outside the green wavelength band λ_{G} differs from the refraction index n_{G} of the green color filter portion 12G substantially, for example and is higher than the refraction index n_{G} of the green color filter portion 12G, for example. The selective reflection portion 29G may be formed in such a manner that a predetermined organic substance such as a metal or an inorganic substance which is different from a substance to be contained in a blue color filter portion 12B is mixed into a transparent resin capable of patterning, in order to adjust the refraction index.

For example, the refraction index n_{G} of the green color filter portion 12G containing the green pigment is about 1.4 to 1.6. When such a green color filter portion 12G is provided, the green color filter portion 12G may be formed by making filler contain in a transparent resin, for example. The selective reflection portion 29G formed in this manner is provided such that the refraction index of the light within the green wavelength band λ_{G} is close to the refraction index of the green color filter portion 12G or coincides with the refraction index of the green color filter portion 12G substantially. Moreover, the selective reflection portion 29G is provided such that the refraction index of the light outside the green wavelength band λ_{G} is quite different from the refraction index of the green color filter portion 12G and becomes higher than the refraction index of the green color filter portion 12G.

As a result of providing the selective reflection portion 29G, the refraction indexes of the green color filter portion 12G and the selective reflection portion 29G with respect to the light within the green wavelength band λ_{G} coincide with each other to become the refraction index n_{G} substantially. Accordingly, as illustrated in FIG. 8C, a green light transmitted through the green color filter portion 12G is not reflected at the interface between the green color filter portion 12G and the selective reflection portion 29G but penetrates into the selective reflection portion 29G.

The refraction indexes of the green color filter portion 12G and the selective reflection portion 29G with respect to a light outside the green wavelength band λ_{G} differ from each other substantially. Accordingly, as illustrated in FIG. 8C, the light other than green light transmitted through the green color filter portion 12G is not absorbed in the green color filter portion 12G but is reflected at the interface between the green color filter portion 12G and the selective reflection portion 29G.

The selective reflection portion 29G is provided so as to have characteristics of refraction index as illustrated in FIG. 8B so that the selective reflection portion 29Git can transmit a green light transmitted through the green color filter portion 12G and reflect a light other than green light at the interface with the green color filter portion 12G.

It is possible to increase the reflection quantity of the light other than green light reflected at the interface more, as the difference between the refraction indexes of the green color filter portion 12G and the selective reflection portion 29G with respect to the light outside the green wavelength band λ_{G} is greater.

As described above, it is sufficient that the selective reflection portion 29G is provided such that the refraction index of the selective reflection portion 29G differs from the refraction index of the green color filter portion 12G with respect to the light outside the green wavelength band λ_{G}. Accordingly, as illustrated by the dotted line in FIG. 8B, the selective reflection portion 29G may be provided such that the refraction index is lower than the refraction index n_{G} of the green color filter portion 12G with respect to the light outside the green wavelength band λ_{G}.

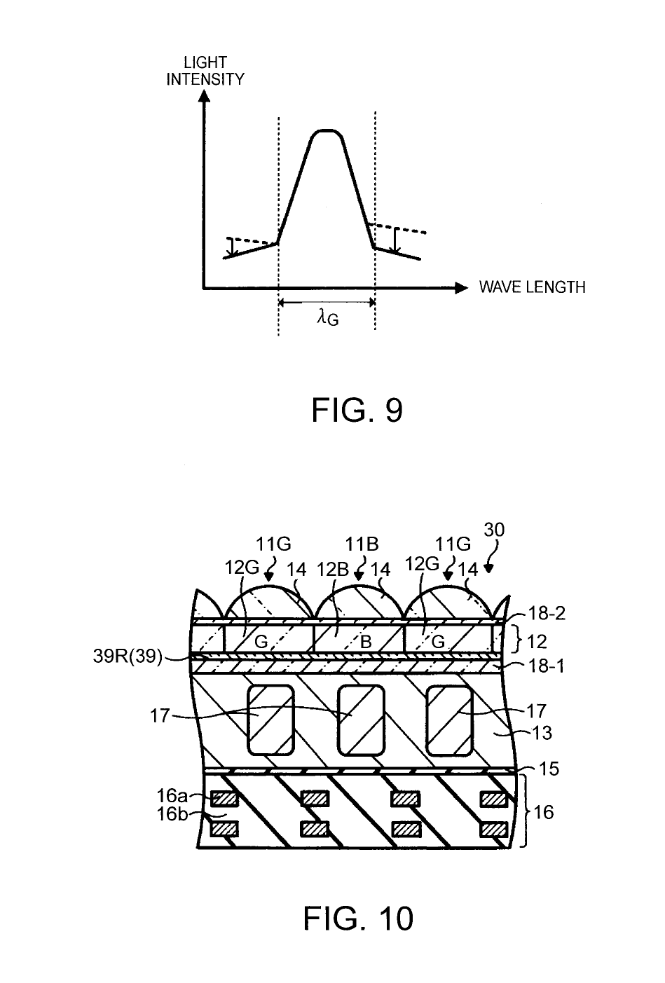

FIG. 9 is a diagram illustrating the wavelength dependence of intensity of light which reaches a light receiving portion 17 in a green pixel 11G having the green color filter portion 12G and the selective reflection portion 29G. As described above, as a result of providing the selective reflection portion 29G, the green light transmitted through the green color filter portion 12G is transmitted through the selective reflection portion 29G to reach the light receiving portion 17 as illustrated in FIG. 9. Accordingly, the green light reaches the light receiving portion 17 at a large light intensity in the green pixel 11G.

A light other than green light which is not absorbed in the green color filter portion 12G but is transmitted through the color filter portion 12G is reflected at the interface between the green color filter portion 12G and the selective reflection portion 29G. Accordingly, the intensity of a light other than green light which reaches the light receiving portion 17 is small in the green pixel 11G.

On the other hand, in a case of a solid-state imaging device not having such a selective reflection portion, almost all of the light other than green light which is transmitted through the green color filter portion in the green pixel reaches the light receiving portion. Accordingly, as illustrated by the dotted line in FIG. 9, the intensity of the light other than green light which reaches the light receiving portion in the green pixel of the solid-state imaging device becomes high compared to that of the green pixel 11G in the solid-state imaging device 20 according to the first modification. This is one of factors which reduce the spectral characteristic in the green pixel.

According to the solid-state imaging device 20 described above, the selective reflection portion 29G is provided between the back surface of a semiconductor substrate 13 and the green color filter portion 12G so as to contact with the green color filter portion 12G. The selective reflection portion 29G has the refraction index which coincides with the refraction index of the green color filter portion 12G substantially with respect to the light within the wavelength band 2G i.e. within the transmission band of the green light transmitted through the green color filter portion 12G and has the refraction index which differs from the refraction index of the green color filter portion 12G substantially outside the transmission band. Accordingly, the spectral characteristic can be favorable in at least the green pixel 11G.

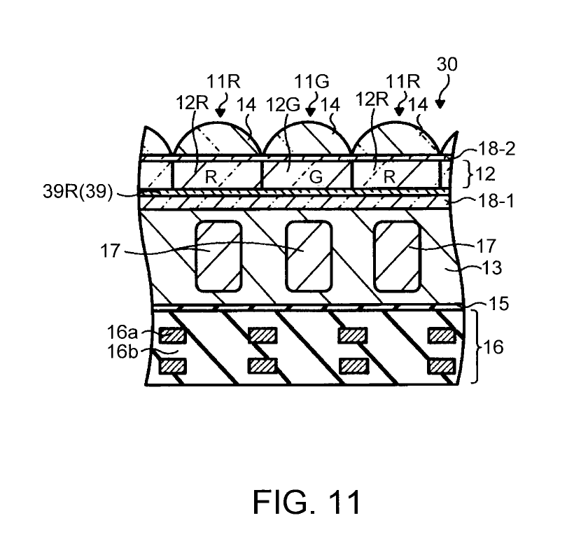

FIGS. 10 and 11 are cross-sectional views illustrating a solid-state imaging device according to a second modification of the first embodiment. FIG. 10 is a cross-sectional view of the solid-state imaging device according to the second modification, which corresponds to FIG. 2. FIG. 11 is a cross-sectional view of the solid-state imaging device according to the second modification, which corresponds to FIG. 3. The top view of the solid-state imaging device according to the second modification is the same as FIG. 1.

As illustrated in FIGS. 10 and 11, in a solid-state imaging device 30 according to the second modification, a selective reflection layer 39 includes one-layered selective reflection portion 39R. The selective reflection portion 39R transmits red light transmitted through a red color filter portion 12R and reflects light other than red light at an interface with the red color filter portion 12R.

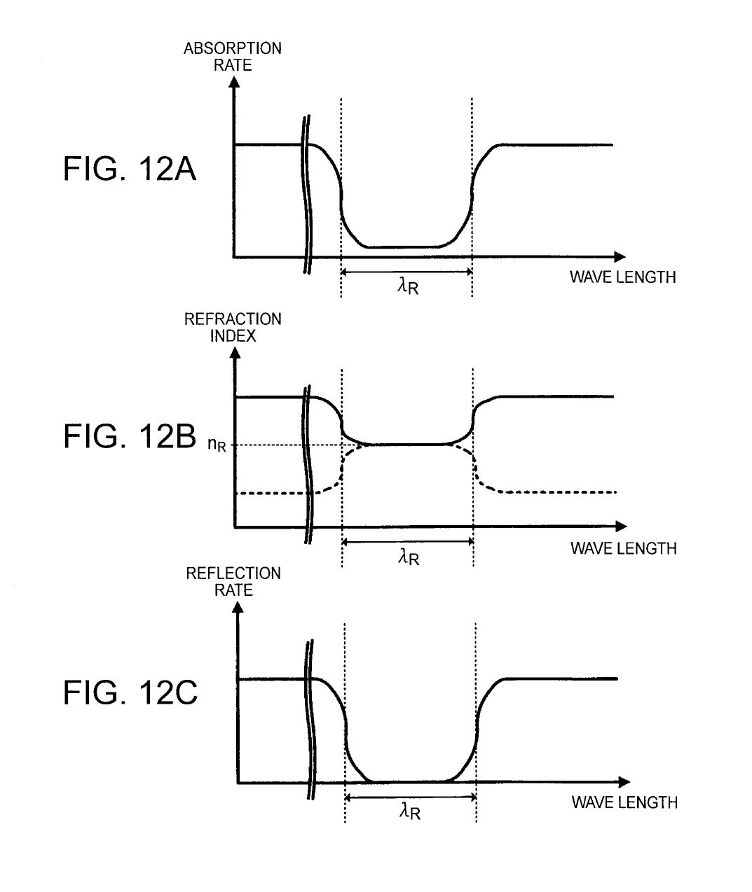

The relation between the red color filter portion 12R and the selective reflection portion 39R will be described below with reference to FIGS. 12A to 12C. FIG. 12A is a diagram illustrating the wavelength dependence of light absorption rate in the red color filter portion 12R. FIG. 12B is a diagram illustrating the wavelength dependence of refraction index of the selective reflection portion 39R. FIG. 12C is a diagram illustrating the wavelength dependence of reflection rate at an interface between the red color filter portion 12R and the selective reflection portion 39R.

As illustrated in FIG. 12A, the red color filter portion 12R is formed by selecting a substance to be contained such that the light absorption rate within a red wavelength band λ_{R} (λ_{R} is about 620 to 750 nm) is low and the light absorption rate outside the red wavelength band λ_{R} is high. For example, a red pigment is mixed into a transparent resin so as to be contained in the transparent resin so that the red color filter portion 12R is formed. The red color filter portion 12R transmits red light and absorbs light other than the red light mostly.

As illustrated in FIG. 12B, the selective reflection portion 39R is provided such that the refraction index of light within the red wavelength band λ_{R} coincides with a refraction index n_{R} of the red color filter portion 12R substantially. Further, the selective reflection portion 39R is provided such that the refraction index of light outside the red wavelength band λ_{R} differs from the refraction index n_{R} of the red color filter portion 12R substantially, and is higher than the refraction index n_{R} of the red color filter portion 12R, for example. The selective reflection portion 39R may be formed in such a manner that a predetermined organic substance such as a metal or an inorganic substance which is different from the contained substance in the blue color filter portion 12B and the green color filter portion 12G is mixed into a transparent resin capable of patterning, in order to adjust the refraction index.

For example, the refraction index n_{R} of the red color filter portion 12R containing the red pigment is about 1.4 to 1.6. When the red color filter portion 12R is provided, the selective reflection portion 39R is formed by mixing filler into the transparent resin so as to be contained in the transparent resin, for example. The selective reflection portion 39R formed in this manner has a refraction index of light within the red wavelength band λ_{R} which is close to the refraction index of the red color filter portion 12R or coincides with the refraction index of the red color filter portion 12R substantially. Moreover, the selective reflection portion 39R has a refraction index of light outside the red wavelength band λ_{R} which is quite different from the refraction index of the red color filter portion 12R and becomes higher than the refraction index of the red color filter portion 12R.

As a result of providing the selective reflection portion 39R, the refraction indexes of the red color filter portion 12R and the selective reflection portion 39R with respect to the light within the red wavelength band λ_{R} coincide with each other and become the refraction index n_{R} substantially. Accordingly, as illustrated in FIG. 12C, a red light transmitted through the red color filter portion 12R is not reflected at the interface between the red color filter portion 12R and the selective reflection portion 39R but penetrates into the selective reflection portion 39R.

The refraction indexes of the red color filter portion 12R and the selective reflection portion 39R with respect to the light outside the red wavelength band λ_{R} differ from each other substantially. Accordingly, as illustrated in FIG. 12C, a light other than red light transmitted through the red color filter portion 12R is not absorbed in the red color filter portion 12R but is reflected at the interface between the red color filter portion 12R and the selective reflection portion 39R.

The selective reflection portion 39R is provided so as to have the refraction index characteristic as illustrated in FIG. 12B so that the selective reflection portion 39R can transmit the red light transmitted through the red color filter portion 12R and reflect the light other than red light at the interface with the red color filter portion 12R.

It is possible to increase the reflection quantity of the light other than red light reflected at the interface more, as the difference between the refraction indexes of the red color filter portion 12R and the selective reflection portion 39R with respect to the light outside the red wavelength band λ_{R} is greater.

As described above, it is sufficient that the selective reflection portion 39R are provided such that the refraction index of the selective reflection portion 39R differs from the refraction index of the red color filter portion 12R with respect to the light outside the red wavelength band λ_{R}. Accordingly, as illustrated by the dotted line in FIG. 12B, the selective reflection portion 39R may be provided such that the refraction index is lower than the refraction index n_{R} of the red color filter portion 12R with respect to the light outside the red wavelength band λ_{R}.

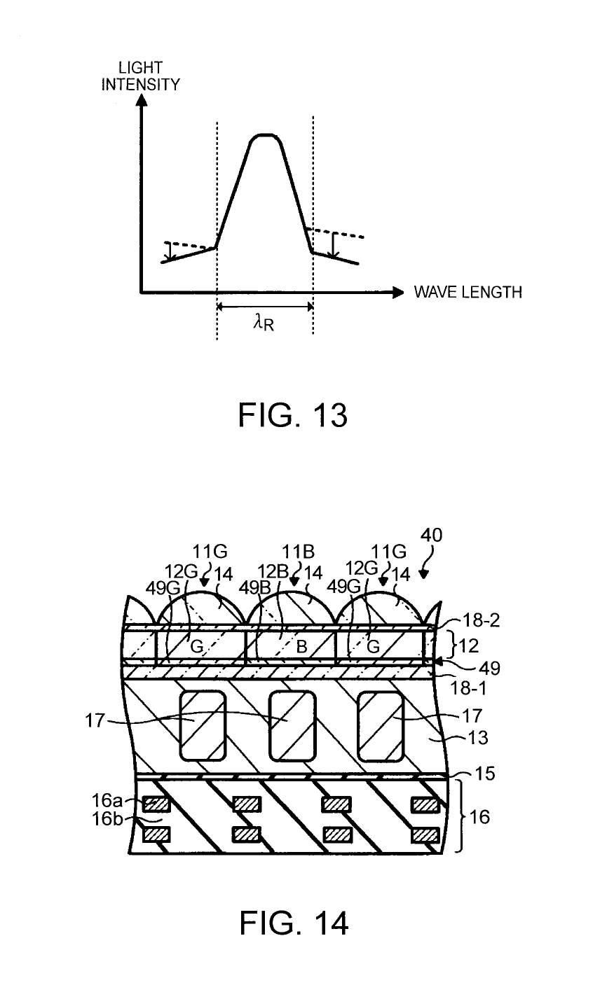

FIG. 13 is a diagram illustrating the wavelength dependence of intensity of light which reaches a light receiving portion 17 within the red pixel 11R having the red color filter portion 12R and the selective reflection portion 39R. As described above, as a result of providing the selective reflection portion 39R, a red light transmitted through the red color filter portion 12R is transmitted through the selective reflection portion 39R to reach the light receiving portion 17 as illustrated in FIG. 13. Accordingly, the red light reaches the light receiving portion 17 at a large light intensity in the red pixel 11R.

A light other than red light which is not absorbed in the red color filter portion 12R but is transmitted through the color filter portion 12R is reflected at the interface between the red color filter portion 12R and the selective reflection portion 39R. Accordingly, the intensity of the light other than red light which reaches the light receiving portion 17 is small in the red pixel 11R.

On the other hand, in a case of a solid-state imaging device not having such a selective reflection portion, almost all of the light other than red light which is transmitted through the red color filter portion in the red pixel reaches the light receiving portion. Accordingly, as illustrated by the dotted line in FIG. 13, the intensity of the light other than red light which reaches the light receiving portion in the red pixel of the conventional solid-state imaging device becomes high compared to that of the red pixel 11R in the solid-state imaging device 30 according to the second modification. This is one of factors which reduce the spectral characteristic in the red pixel.

According to the solid-state imaging device 30 of the second modification described above, the selective reflection portion 39R is provided between the back surface of a semiconductor substrate 13 and the red color filter portion 12R so as to contact with the red color filter portion 12R. The selective reflection portion 39R has a refraction index which coincides with the refraction index of the red color filter portion 12R substantially with respect to the light within the wavelength band λ_{R} i.e. within the transmission band of the red light transmitted through the red color filter portion 12R. Further, the selective reflection portion 39R has a refraction index which differs from the refraction index of the red color filter portion 12R substantially with respect to a light outside the transmission band. Accordingly, the spectral characteristic can be favorable in at least the red pixel 11R.

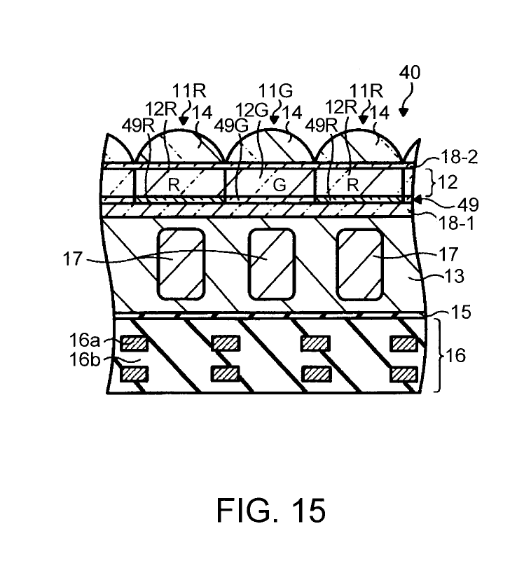

FIGS. 14 and 15 are cross-sectional views illustrating a solid-state imaging device according to a second embodiment. FIG. 14 is a cross-sectional view of the solid-state imaging device according to the second embodiment, which corresponds to FIG. 2. FIG. 15 is a cross-sectional view of the solid-state imaging device according to the second embodiment, which corresponds to FIG. 3. The top view of the solid-state imaging device according to the second embodiment is the same as FIG. 1.

A solid-state imaging device 40 according to the second embodiment is different in structure of a selective reflection layer from the solid-state imaging device 10 according to the first embodiment.

As illustrated in FIGS. 14 and 15, in the solid-state imaging device 40, a selective reflection layer 49 is provided to reflect light selectively depending on a wavelength of incident light, and includes selective reflection portions 49B, 49G, 49R provided in pixels 11B, 11G, 11R, respectively. Each of the selective reflection portions 49B, 49G, 49R has substantially the same refraction index as each of the color filter portions 12B, 12G, 12R with respect to light within the transmission band of each of the color filter portions 12B, 12G, 12R which corresponds to each of the selective reflection portions. Further, each of the selective reflection portions 49B, 49G, 49R has a refraction index which is substantially different from that of each of the color filter portions with respect to light outside the transmission band.

The selective reflection portion 49B has the refraction index characteristic illustrated in FIG. 4B. The selective reflection portion 49B is provided between the back surface of a semiconductor substrate 13 and the blue color filter portion 12B so as to contact with the blue color filter portion 12B. The selective reflection portion 49G has the refraction index characteristic illustrated in FIG. 8B. The selective reflection portion 49G is provided between the back surface of the semiconductor substrate 13 and the green color filter portion 12G so as to contact with the green color filter portion 12G. Moreover, the selective reflection portion 49R has the refraction index characteristic illustrated in FIG. 11B. The selective reflection portion 49R is provided between the back surface of the semiconductor substrate 13 and the red color filter portion 12R so as to contact with the red color filter portion 12R. In the solid-state imaging device 40, the selective reflection layer 49 includes three kinds of the selective reflection portions 49B, 49G, 49R.

According to the solid-state imaging device 40, each of the selective reflection portions 49B, 49G, 49R is provided between the back surface of the semiconductor substrate 13 and each of the color filter portions 12B, 12G, 12R so as to contact with each of the color filter portions 12B, 12G, 12R. Each of the selective reflection portions 49B, 49G, 49R has substantially the same refraction index as each of the color filter portions 12B, 12G, 12R with respect to light within each of the wavelength bands λ_{B}, λ_{G}, and λ_{R} i.e. within each of the transmission bands of light transmitting through each of the color filter portions 12B, 12G, 12R which corresponds to each of the selective reflection portions. Further, each of the selective reflection portions 49B, 49G, 49R has the refraction index which is substantially different from that of each of the color filter portions 12B, 12G, 12R with respect to light outside each of the transmission bands. Accordingly, the spectral characteristics can be favorable in each of the pixels 11B, 11G, 11R.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

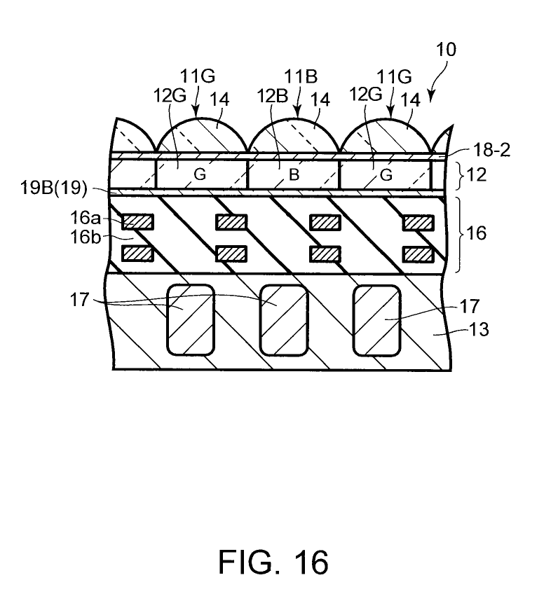

For example, the above-described embodiments relate to a back-surface-irradiation-type solid-state imaging device. The invention is also similarly applicable to a so-called front-surface-irradiation-type solid-state imaging device. FIG. 16 is a cross-sectional view of a solid-state imaging device of a front-surface-irradiation-type according to a third modification of the first embodiment, which corresponds to FIG. 2. In the solid-state imaging device, color filter layer 12G, 12B and microlenses 14 are provided on a front surface i.e. a second main surface of a semiconductor substrate 13 in which light receiving portions 17 are formed, via a layer 16 having interconnections 16a insulated with an interlayer insulating film 16b. A selective reflection portion 19B which transmits blue light is formed between the layer 16 and the color filter portion 12G, 12B.

1. A solid-state imaging device comprising:
a semiconductor substrate having light receiving portions;
a color filter layer provided above a first main surface of the semiconductor substrate and having a blue color filter portion, a green color filter portion and a red color filter portion, the blue color filter portion having a transmission band for transmitting blue light to absorb light outside the transmission band, the green color filter portion having a transmission band for transmitting green light to absorb light outside the transmission band, the red color filter portion having a transmission band for transmitting red light to absorb light outside the transmission band; and
a selective reflection layer provided between the first main surface of the semiconductor substrate and the color filter layer and having a first selective reflection portion, a second selective reflection portion and a third selective reflection portion, wherein
the first selective reflection portion is provided so as to contact with the blue color filter portion, the first selective reflection portion has substantially the same refraction index as the blue color filter portion with respect to light within the transmission band of the blue light and the refraction index of the first selective reflection portion is substantially different from that of the blue color filter portion with respect to light outside the transmission band of the blue light,
the second selective reflection portion is provided so as to contact with the green color filter portion, the second selective reflection portion has substantially the same refraction index as the green color filter portion with respect to light within the transmission band of the green light and the refraction index of the second selective reflection portion has a refraction index which is substantially different from that of the green color filter portion with respect to light outside the transmission band of the green light, and
the third selective reflection portion is provided so as to contact with the red color filter portion, the third selective reflection portion has substantially the same refraction index as the red color filter portion with respect to light within the transmission band of the red light and the refraction index of the third selective reflection portion has a refraction index which is substantially different from that of the red color filter portion with respect to light outside the transmission band of the red light.

2. The solid-state imaging device according to claim 1, wherein microlenses are provided above the color filter layer.

3. The solid-state imaging device according to claim 1, wherein the blue color filter portion, the green color filter portion, and the red color filter portion are Bayer-arrayed.

4. The solid-state imaging device according to claim 1, further comprising a layer including an interconnection which is formed on a side of a second main surface of the semiconductor substrate opposite to the first main surface of the semiconductor substrate.

5. The solid-state imaging device according to claim 1, further comprising a flattened layer provided between the first main surface of the semiconductor substrate and the selective reflection layer.

6. A solid-state imaging device comprising:
a semiconductor substrate having a light receiving portion;
a color filter layer provided above a first main surface of the semiconductor substrate and including a color filter portion which has a transmission band for transmitting light of a predetermined wavelength band and which absorbs light outside the transmission band; and
a selective reflection layer provided between the first main surface of the semiconductor substrate and the color filter layer so as to contact with the color filter portion, the selective reflection layer having substantially the same refraction index as the color filter portion with respect to light within the transmission band, the refraction index of the selective reflection layer being substantially different from that of the color filter portion with respect to light outside the transmission band.

7. The solid-state imaging device according to claim 6, wherein microlenses are provided above the color filter layer.

8. The solid-state imaging device according to claim 6, further comprising a layer including an interconnection which is formed on a side of a second main surface of the semiconductor substrate opposite to the first main surface of the semiconductor substrate.

9. The solid-state imaging device according to claim 6, further comprising a flattened layer provided between the first main surface of the semiconductor substrate and the selective reflection layer.

10. The solid-state imaging device according to claim 6, wherein
the semiconductor substrate has light receiving portions including the light receiving portion of the semiconductor substrate,
the color filter layer has color filter portions including the color filter portion of the color filter layer, the color filter portions have different transmission bands of light, and
the selective reflection layer has selective reflection portions including the selective reflection portion, each of the selective reflection portions being provided so as to contact with each of the corresponding color filter portions, each of the selective reflection portions having substantially the same refraction index as that of each of the corresponding color filter portions with respect to light within the transmission band and having a refraction index which is substantially different from that of each of the corresponding color filter portions with respect to light outside the transmission band of each of the corresponding color filter portions.

11. The solid-state imaging device according to claim 10, wherein the color filter portions are a blue color filter portion in which the transmission band is a blue wavelength band, a green color filter portion in which the transmission band is a green wavelength band, and a red color filter portion in which the transmission band is a red wavelength band, respectively.

12. The solid-state imaging device according to claim 11, wherein the blue color filter portion, the green color filter portion, and the red color filter portion are Bayer-arrayed.

13. A solid-state imaging device comprising:
a semiconductor substrate provided with a light receiving portion;
a layer having an interconnection which is formed above a first main surface of the semiconductor substrate;
a color filter layer provided above the layer having the interconnection, the color filter layer including a color filter portion which has a transmission band for transmitting light of a predetermined wavelength band and which absorbs light outside the transmission band; and
a selective reflection layer provided between the first main surface of the semiconductor substrate and the color filter layer so as to contact with the color filter portion, the selective reflection layer having substantially the same refraction index as the color filter portion with respect to light within the transmission band, the refraction index of the selective reflection layer being substantially different from that of the color filter portion with respect to light outside the transmission band.

14. The solid-state imaging device according to claim 13, wherein microlenses are provided above the color filter layer.

15. The solid-state imaging device according to claim 13, further comprising a flattened layer provided between the first main surface of the semiconductor substrate and the selective reflection layer.

16. The solid-state imaging device according to claim 13, wherein
the semiconductor substrate has light receiving portions including the light receiving portion of the semiconductor substrate,
the color filter layer has color filter portions including the color filter portion of the color filter layer, the color filter portions have different transmission bands of light, and
the selective reflection layer has selective reflection portions including the selective reflection portion, each of the selective reflection portions being provided so as to contact with each of the corresponding color filter portions, each of the selective reflection portions having substantially the same refraction index as that of each of the corresponding color filter portions with respect to light within the transmission band and having a refraction index which is substantially different from that of each of the corresponding color filter portions with respect to light outside the transmission band of each of the corresponding color filter portions.

17. The solid-state imaging device according to claim 13, wherein the color filter portions are a blue color filter portion in which the transmission band is a blue wavelength band, a green color filter portion in which the transmission band is a green wavelength band, and a red color filter portion in which the transmission band is a red wavelength band, respectively.

18. The solid-state imaging device according to claim 14, wherein the blue color filter portion, the green color filter portion, and the red color filter portion are Bayer-arrayed.
